(19) United States
(12) Patent Application Publication
(10) Pub. No.: US 2008/0203399 A1
(43) Pub. Date: Aug. 28, 2008

(54) POLARIZATION DOPED TRANSISTOR CHANNELS IN SIC HETEROPOLYTYPES

(76) Inventors: Michael G. Spencer, Ithaca, NY (US); Christopher Ian Thomas, Ithaca, NY (US); MVS Chandrashekhar, Ithaca, NY (US)

Correspondence Address: JONES, TULLAR & COOPER, P.C., P.O. BOX 2266 EADS STATION, ARLINGTON, VA, 22202, US

(21) Appl. No.: 11/857,412

(22) Filed: Sep. 18, 2007

Related U.S. Application Data
(60) Provisional application No. 60/845,253, filed on Sep. 18, 2006.

(51) Int. Cl. H01L 29/24

(52) U.S. Cl. 257/77; 257/E29.104

(57) ABSTRACT

Heteropolytype SiC heterojunctions display an abrupt change in polarization leading to 2 dimensional electron or hole gases at the lattice matched interface, depending on the direction of polarization. These channels carry a large amount of electric current which can be modulated with a gate electrode, giving rise to transistor operation in the lateral geometry without the need for n or p type doping. Furthermore, some of these structures display high turn-on voltages which may have applications in terahertz sources and exotic diodes in the transverse geometry.

### CROSS REFERENCE TO RELATED APPLICATIONS

This application claims the benefit, under 35 U.S.C. 119(e), of U.S. Provisional Application No. 60/845,253, filed Sep. 18, 2006, which is hereby incorporated by reference in its entirety.

### GOVERNMENT SPONSORSHIP STATEMENT

The work on this invention was supported by the Office of Naval Research under Grant No. N00014.04.1.0033. The Government has certain rights in the invention.

### BACKGROUND OF THE INVENTION

1. Field of the Invention

The present invention relates to heteropolytype SiC junctions which display an abrupt change in polarization leading to 2 dimensional electron or hole gases at the interface, depending on the direction of polarization. These channels carry a large amount of electric current which can be modulated with a gate electrode, giving rise to transistor operation in the lateral geometry. Furthermore, some of these structures display high turn-on voltages which may have applications in terahertz sources and exotic diodes in the transverse geometry.

2. Description of the Background Art

Semiconductor heterojunctions are usually formed by a compositional change such as in the GaAs/AlₓGa₁₋ₓAs, Si/Si₁₋ₓGeₓ, and GaN/AlₓGa₁₋ₓN systems. There is, however, another class of heterojunction that uses different crystal configurations of only one semiconductor to form the junction. The different crystal configurations are realized purely through an abrupt change in stacking sequence [1]. Silicon Carbide (SiC) is capable of forming such a junction.

SiC crystallizes into over 200 different crystal arrangements called polytypes [2]. While there are other materials that show this tendency, for example ZnS, GaN, and CdS, SiC is unique in that the different polytypes have markedly different electronic properties. Table 1 shows the wide range of variation of the bandgaps of the major polytypes from 2.3 eV (3C—SiC) to 3.3 eV (2H—SiC). Note that this trend tracks the degree of hexagonality of the polytype. For ZnS, GaN, and CdS the variation in bandgap with polytype is <0.1 eV.

TABLE 1
Basic properties of the major SiC polytypes

| | Bandgap | Crystal | | Hexagonality |
|---|---|---|---|---|
| | (eV) | Structure | P_{SP} (C/m²) | (%) |
| 2H | 3.3 | wurtzite | 0.04 | 100 |
| 4H | 3.2 | wurtzite | 0.02 | 40 |
| 6H | 3 | wurtzite | 0.01 | 33.33 |
| 15R | | Rhombohedral | — | 40 |
| 3C | 2.3 | Cubic | 0 | 0 |

Like GaN, the covalent bonds in SiC demonstrate a certain degree of ionicity due to the small C-atom. This means SiC polytypes that lack inversion symmetry (wurtzite and rhombohedaral) should demonstrate some form of macroscopic polarization. Qteish et al. used a first principles pseudopotential approach [3] to determine the direction and magnitude of the spontaneous polarization in purely hexagonal 2H—SiC. Using this technique the spontaneous polarization in 2H—SiC was predicted to be 4.32×10⁻² C/m², which is higher than in GaN. The direction of the spontaneous polarization vector was determined to be from the carbon to silicon atom i.e. in the [000-1] direction.

Because of their structural simplicity, Qteish et al used the 2H and 3C polytypes (purely cubic) to simplify their calculations. Work on 2H SiC, however, has been limited as it is metastable [4]. The spontaneous polarization in 2H—SiC is, however, still important, because, like the bandgap, the degree of spontaneous polarization varies with the hexagonality of the polytype. Therefore, the 2H—SiC value can be used to estimate the spontaneous polarization in other polytypes. Table 1 shows that the adjusted spontaneous polarization values for 4H and 6H—SiC (extrapolated linearly from degree of hexagonality) compare favorably with that of GaN.

The smaller bandgap of 3C—SiC relative to its hexagonal counterparts, makes it an ideal choice for the formation of a SiC polytype heterojunction. 3C—SiC/4H—SiC and 3C—SiC/6H—SiC heterojunctions with conduction band offsets of 0.99 eV and 0.7 eV respectively are of the most interest. The valence band offset can sometimes be neglected as it is small ˜0.1 eV. In addition, 3C is the thermodynamically favorable form of SiC [5] and is therefore relatively easy to realize on a hexagonal substrate.

The different SiC polytypes are lattice matched to within 0.1% [5] in the [0001] direction, which allows the realization of not only unstrained layers, but also high quality interfaces. This means that there is no piezoelectric polarization to take into consideration. The direction of polarization in hexagonal SiC predicts the formation of a 2DEG on the carbon terminated surface (or C-face), while a 2 dimensional hole gas (2DHG) is predicted for the silicon terminated surface (or Si-face) of <0001> hexagonal SiC.

Of the over 200 SiC polytypes, the most common are 4H, 6H, 3C, and 15R. Early attempts at SiC growth resulted in a mixture of the polytypes. There are now pure commercial substrates available up to 4 inches for 4H and 6H, both conductive and insulating. The 3C polytype is the most thermodynamically stable of the polytypes and can be grown on hexagonal substrates to readily form a cubic/hexagonal stacking sequence.

The thermodynamics of the system make it much more difficult to grow hexagonal SiC on 3C. There have been reports of 6H grown unintentionally on 3C, either through stacking faults [6] or through carefully prepared MBE-grown systems [7]. Polytype conversions through annealing and transitions during high sublimation growth temperatures have also been reported, leading to another route for the preparation of hexagonal SiC stacked on 3C [4]. Polytype control in all of these systems is extremely difficult and thus not suitable for systematic investigation or for fabrication of transistors. This makes the SiC heteropolytype system markedly different from the AlGaN/GaN system as no wide bandgap barrier layer can be grown under the gate metal forcing the gate to be on the narrow-gap 3C SiC.

Despite the growth constraints, the 3C/hexagonal heteropolytype system is very attractive owing to the large conduction band offsets and appreciable spontaneous polarization induced charge (see Table 2) in these heterostructures. This allows the ability to realize lattice mismatch free SiC HEMT's with performance comparable to the successful AlGaN/GaN HEMTs.

TABLE 2
Relevant heteropolytype parameters for technologically important
junctions

| | | | | Lattice |
|---|---|---|---|---|
| Heterojunction | CBO (eV) | P_{SP} (C/m²)^{a)} | P_{SP} direction | Mismatch(%)^{b)} |
| 3C/4H—SiC | 0.99 | 2.16 × 10⁻² | [000-1] | 0.08 |
| 3C/6H—SiC | 0.7 | 1.44 × 10⁻² | [000-1] | 0.05 |

^{a)}Ref. [3]
^{b)}Ref. [5]

There is a large body of work on polytype controlled epitaxy using standard growth techniques like chemical vapor deposition (CVD), molecular beam epitaxy (MBE), and sublimation [7-9]. Most of these studies involve homoepitaxy of hexagonal SiC.

There are very few reports of the growth of SiC heteropolytype structures using MBE. For a thorough discussion, please see the excellent review by Fissel [7]. There have been other reports of heteropolytype junction growth using sublimation epitaxy and chemical vapor deposition (CVD). Most of the initial work, however, was done on the Si-face with a heavy emphasis on p-n heterojunctions and material optimization [10, 11].

### SUMMARY OF THE INVENTION

The invention is directed toward formation of specific SiC polytype based heterojunctions that employ spontaneous polarization to facilitate charge transfer in two and three terminal heterojunction based devices. More specifically, the invention relates to the formation of SiC heterojunctions using 3C/4H—SiC and 3C/6H—SiC.

### BRIEF DESCRIPTION OF THE DRAWINGS

The features and advantages of the invention will become apparent from the following detailed description of a number of preferred embodiments thereof, taken in conjunction with the following drawings.

FIGS. 1A and 1B are TLM measurements of 3C/4H mesas on semi-insulating-4H SiC substrates. FIG. 1A shows the pulsed IV characteristics for different spacings. Saturation is clearly seen. FIG. 1B shows the extracted sheet resistance of the heterostructure.

FIGS. 2A and 2B are predicted electron concentration in a hexagonal/cubic SiC heteropolytype quantum well. The Schottky barrier in this case is on the hexagonal side, whereas as grown heteropolytypic structures would have a Schottky barrier on the cubic side. Courtesy Polyakov and Schwierz [50].

FIG. 3 shows the electron concentration extracted from capacitance voltage profiling of a 3C/6H heterostructure grown on a semi-insulating 6H substrate. The 2DEG is seen clearly with a debye tail extending into the substrate [55].

FIGS. 4A and 4B show the energy band diagram and charge balance, respectively, for 3C/4H heteropolytype junction grown on the Si-face of n⁺ 4H SiC.

FIGS. 5A and 5B are graphs showing the 1 MHz CV characteristic, and the IV characteristic, respectively, of 3C/4H heteropolytype junctions grown on n⁺ SiC.

FIG. 6 shows the Simulated 2DHG concentration and confinement as a function of applied voltage for the situation illustrated in FIG. 7. The 2DHG full width half maximum is <3 nm over the entire range simulated.

FIG. 7 shows the hole concentration extracted from measured CV characteristic of a 3C/4H Si-face heteropolytype junction grown on a semi-insulating 4H SiC substrate.

FIG. 8 is a schematic of a 3C/Hexagonal or Rhombohedral SiC HEMT constructed in accordance with the present invention.

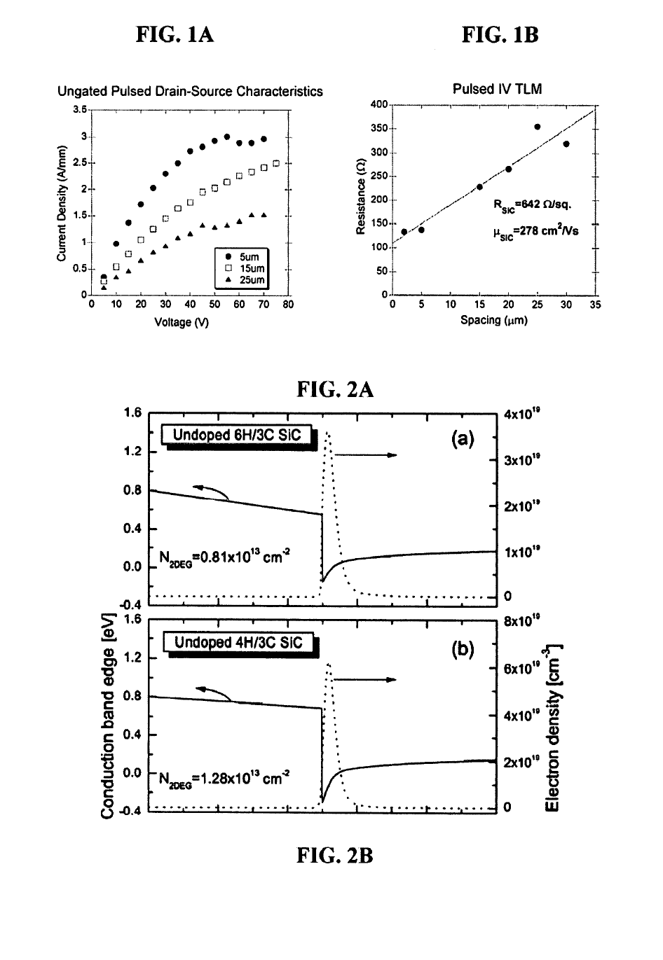

### DETAILED DESCRIPTION OF THE PREFERRED EMBODIMENTS

The following provides a detailed description of the growth of the growth and characterization of the 3C/4H—SiC and 3C/6H—SiC heterojunctions.

CVD Growth of 3C/4H—SiC and 3C/6H—SiC Polytype Heterojunctions

SiC CVD is typically carried out between 1300° C.-1700° C. at pressures ranging from 50 Torr-760 Torr. Silane (SiH₄) and hydrocarbon precursors are used to supply Si and C, respectively, in a hydrogen ambient. The growth rate and surface kinetics are determined by Si vapor pressure. Liquid Si adsorbing on the surface is believed to mediate the reaction. Nitrogen and phosphorus are the most commonly used n-type dopants while aluminum and boron are the most common n-type dopants.

Most of the work on SiC CVD has been done on the Si-face [8]. This is because the surface energy on the Si-face is much higher (for Si face vs. for C face), leading to much more controlled nucleation and growth. However, the 2DEG is favored on the C-face. Thus, it is necessary to gain a complete understanding of the growth on the C-face. There have been a few reports of heteroepitaxy of 3C on the C-face [12]. Control of the polytype uniformity during SiC growth involves control of the following:

(i) The surface supersaturation
(ii) The temperature
(iii) Substrate quality and surface preparation
(iv) Surface migration length

### (v) Impurities

Homoepitaxy of hexagonal SiC occurs through step-flow growth. Step-flow is promoted by making the surface migration length of reactants much larger than the terrace width. This is achieved through both using substrates cut off-axis from vicinal surfaces and by increasing temperature.

Heteroepitaxy of 3C SiC occurs through terrace nucleation. This is promoted by using on-axis substrates and by reducing surface migration length by decreasing temperature. Decreasing temperature has the added benefit of reducing desorption of adatoms from the surface. Desorption of adatoms would tend to promote step flow growth, which would promote homoepitaxy. Despite the lower surface energy on the C-face, the surface migration lengths are much longer compared to the Si-face, which has shorter migration lengths due to the favorability of desorption [13].

Polytype control is thus dependent on being able to control the surface migration length of adatoms on the SiC surface with respect to the terrace widths. The migration length can also be controlled, to a certain extent, by varying the C/Si ratio at the surface of the growing crystal [7].

The C/Si ratio determines the quality and morphology of the material grown. The ratio can also determine the unintentional impurity incorporation into the crystal (site-competition epitaxy [14]). The C-face favors higher nitrogen incorporation than the Si-face. Thus, careful optimization of temperature and C/Si ratio are critical to obtaining high quality, low doped material for the investigation of the polarization doped heterostructures. Please see the report by Neudeck et al [10] for a thorough review of Si-face heterojunction growth. In the remainder of this section, we will restrict ourselves to C-face material considerations.

In order to promote 3C nucleation on the C-face and suppress hexagonal polytype growth, temperatures below 1400° C. are desirable. Furthermore, due to the low surface energy, it is desirable to minimize the growth rate to prevent onset of 3D Vollmer-Weber growth and promote layer-by-layer growth for optimal material quality. By varying the C/Si ratio, the material morphology can be controlled. Scanning electron micrographs were generated documenting change of morphology with inlet C/Si ratio on on-axis <0001> C-face 4H SiC substrates at 1400° C. A vertical cold-wall spinning disk reactor was used in this study with C/Si=0.8; C/Si=1; and C/Si=1.5. The optimized morphology shows various islands believed to originate from double positioning boundaries (DPB's). The morphology clearly showed a transition from columnar growth for carbon rich conditions (indicative of short migration lengths) to more island-like growth at higher Si-contents. At high Si ratios, large amounts of Si form pools of Si on the surface which can serve as nucleation sites for amorphous SiC. The optimized morphology displays various islands. These are believed to originate from the twinned nature of the 3C polytype, giving rise to double positioning boundaries (DPBs).

Table 3 shows van der Pauw configuration Hall-mobility data for 3C grown on C-face semi-insulating 4H substrates for electrical isolation. The increase in mobility with decreasing temperature and the large persistent charge is suggestive of a large 2DEG at the interface. The charge density is consistent with calculations by Polyakov and Schwierz [15]. Pulsed current-voltage transmission line model (TLM) measurements showed sheet resistance consistent with the van der Pauw resistance. Saturation current levels of 3 A/mm were measured, which compare very well with GaN/AlGaN HEMTs. Such high current channels could be used for microwave devices. These current levels and the persistent charge at low temperature strengthen the case for the presence of a 2DEG at the interface, as predicted. The charge balance in this system will be dealt with in greater detail below.

TABLE 3
Representative van der Pauw configuration Hall measurements on
3C/4H heteropolytype junctions grown on semi-insulating substrates.

| | |
|---|---|
| Sample A | Sample B |

| | | | | |
|---|---|---|---|---|
| T(K) | 300 | 77 | 300 | 77 |
| nₛ | 3.5 | 2.5 | 3.65 | 2.39 |
| (10¹³ cm⁻²) | | | | |
| Rₛ | 880 | 800 | 971 | 1285 |
| (Ω/) | | | | |
| μ | 200 | 300 | 190.5 | 247.5 |
| (cm²/V · s) | | | | |

SiC Heteropolytype Structures

1. Carbon Face

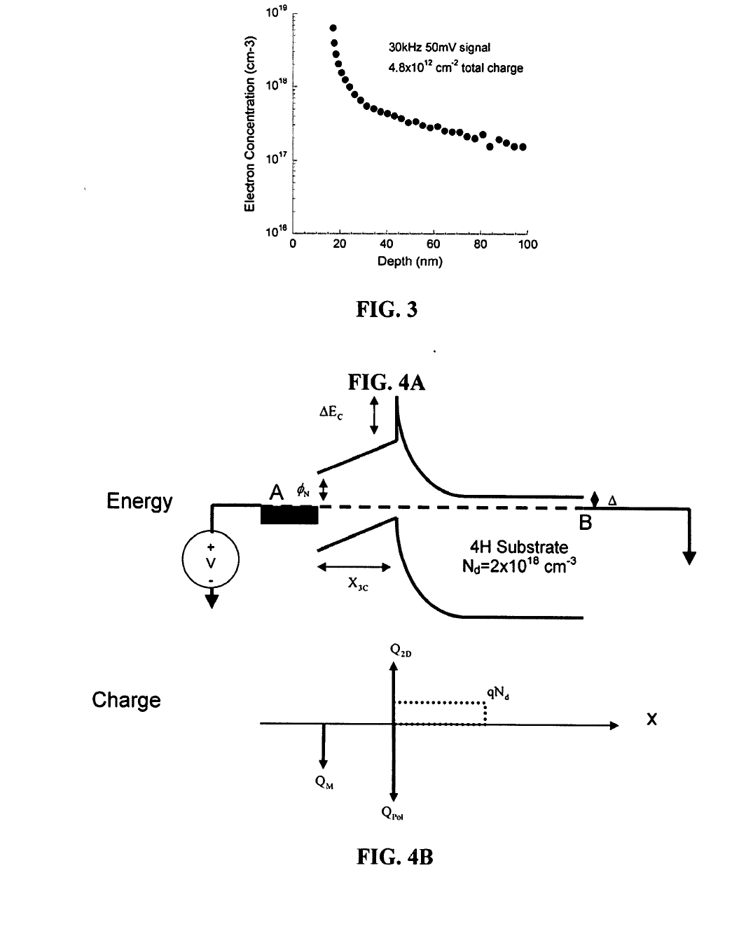

As discussed previously, the formation of a two dimensional electron gas (2DEG) is favored on the (0001) C-face of 4H/6H SiC. The spontaneous polarization leaves a fixed positive charge on the surface of the hexagonal SiC. This induces a free electron mirror charge in the quantum well formed in the non-polar 3C. Owing to the large conduction band offset between 3C and 4H (0.99 eV)/6H (0.7 eV), the quantum well formed can accommodate a large amount of charge, which in this case is provided by polarization. FIGS. 2A and 2B show the band diagram and predicted carrier profile in such a quantum well [15]. FIG. 3 shows the carrier concentration extracted from capacitance-voltage (CV) measurements of a 3C/6H heterostructure, clearly showing the presence of the 2DEG at the interface.

Capacitance voltage carrier profiles are slightly distorted from the true equilibrium profiles due to Debye-smearing effects. However, the total measured charge must equal the equilibrium charge [16]. The discrepancy between the charge predicted by Polyakov [15] (8.1×10¹² cm⁻²) and that measured in FIG. 6 (4.8×10¹² cm⁻²) may be due to parasitic surface and interface charges from imperfect interface preparation. This bears further investigation, in analogy with the GaN/AlGaN case discussed previously.

Further work on C-face-electrostatics will involve refining the models to accurately reflect the growth of the 3C on the hexagonal substrate, which forces the Schottky barrier to be on the cubic side, rather than on the wide bandgap hexagonal side, as in the GaN/AlGaN system. It is also important to understand surface preparation and surface charge instability of the grown heterostructure in order to be able to controllably deposit gate metal with repeatable barrier height and stabilize drain current.

2. Silicon Face

The <0001> Si-face of 4H/6H SiC favors the formation of a two dimensional hole gas (2DHG). The spontaneous polarization leaves a fixed negative charge on the surface of the hexagonal SiC, implying a mirror free hole charge in the non-polar 3C. Considering that the valence-band offset is ˜0.1 eV [3], which is small considering the large polarization charge predicted (−1.5×10¹³ cm⁻²), the confinement of the mirror free-hole charge appears uncertain. However, the large polarization charge also induces a large polarization field in a thin 3C layer, leading to severe band banding in the 3C, forcing an almost purely-polarization induced quantum-well in the valence band. FIGS. 4A and 4B illustrate this situation for an n⁺ 4H SiC substrate [17].

Invoking Gauss' law at the hetero-interface,

$$\begin{matrix}{F}_{2} = {F}_{1} + \frac{{Q}_{Interface}}{ɛ} = \frac{{Q}_{M}}{ɛ} + \frac{[ {Q}_{Pol} + {Q}_{2 D} ]}{ɛ} = - \frac{{qN}_{d} {x}_{d}}{ɛ} & ( 9 a ) \\ {Q}_{M} = - {qN}_{d} {x}_{d} - [ {Q}_{Pol} + {Q}_{2 D} ] & ( 9 b )\end{matrix}$$

where x_{d} is the depletion width in the substrate, Q^{pot} the fixed polarization charge, Q_{2D} the hole gas free charge, Q_{M} the charge on the Schottky metal, N_{d} the doping concentration in the substrate. ∈ is the SiC dielectric constant, which is 9.7∈₀.

Taking a potential loop from A to B, starting and ending at the Fermi level,

$$\frac{{φ}_{N}}{q} + \frac{{Q}_{M}}{ɛ} {X}_{3 C} + \frac{Δ {E}_{C}}{q} - \frac{{qN}_{d} {x}_{d}^{2}}{ɛ} - \frac{Δ}{q} = 0 \qquad ( 10 )$$

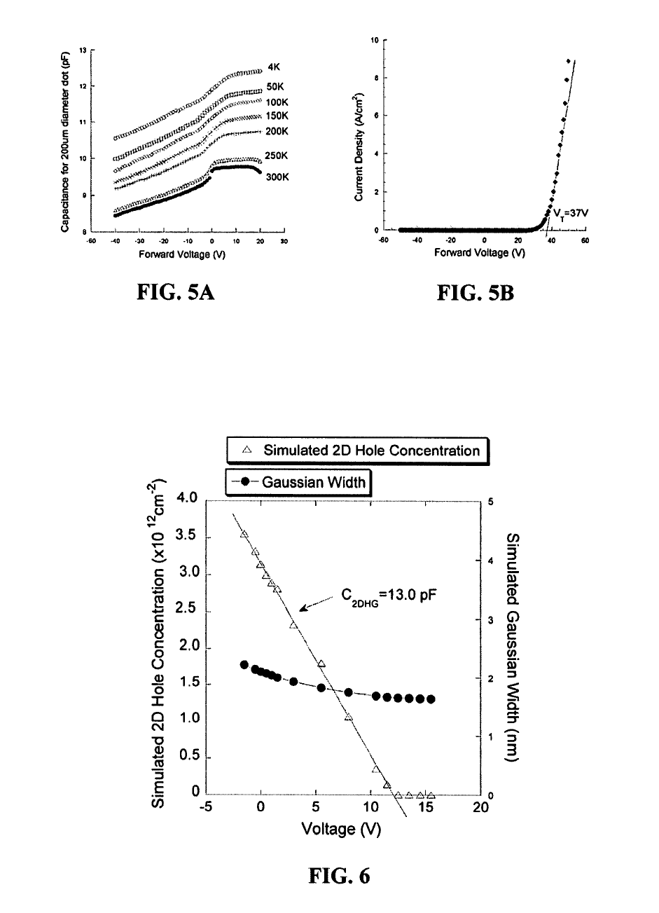

Taking applied voltage to be very positive, so that the hole-gas is completely depleted (i.e. Q_{2D}=0), we replace φ_{N} with φ_{N}−V and solve (9) and (10) simultaneously,

$${x}_{d} + {X}_{3 C} = \frac{{X}_{3 C} + \sqrt{{X}_{3 C}^{2} + 4 \frac{C - V - \frac{[ {Q}_{Pol} ] {X}_{3 C}}{ɛ}}{\frac{{qN}_{d}}{ɛ}}}}{2} \qquad ( 11 )$$

where C=(φ_{N}+ΔE_{C}−Δ)/q□1.5V, assuming a Schottky barrier height of 0.5 eV. This thickness corresponds to the measured capacitance in the extreme positive voltage region (see FIGS. 5A and 5B). Furthermore, one can predict the turn-on voltage V_{T} of this heterodiode by setting x_{d}=0, at which point all band-bending in the substrate is relieved and electrons can flow unimpeded into the 3C region.

$$V = C - \frac{[ {Q}_{pol} ] {X}_{3 C}}{ɛ} = {V}_{T} \qquad ( 12 )$$

FIGS. 5A and 5B shows measured CV and IV characteristics of this heterojunction. The turn on voltage and forward bias capacitance are measured, and can be inserted into equations (11) and (12). Solving these equations simultaneously yields the fixed polarization charge Qₚₒₜ and the thickness of the 3C epitaxial layer x_{3C}. The polarization charge density extracted using this method, 9.7×10¹² cm⁻², agrees well with that extracted from polarization induced Stark shift measurements from photoluminescence studies of stacking faults in SiC epitaxial layers [6].

It is interesting to note that the 2 dimensional hole gas (2DHG) does not show up explicitly in the CV characteristic due to the high frequency, but is inferred, in analogy with a MOS capacitor. In order to predict the 2DHG density, the measured polarization charge was inserted into a Schrödinger-Poisson solver yielding the charge density and confinement of the 2DHG as a function of applied voltage (FIG. 6). It is seen that the 2DHG is strongly confined by the polarization (a zero valence band offset was assumed to simplify the calculation).

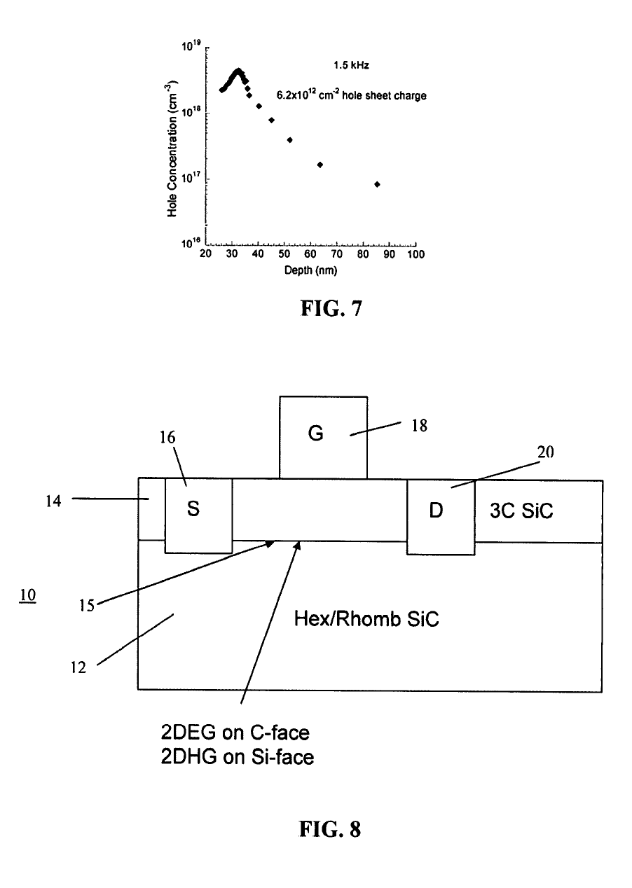

As the positive charge on the metal depletes the 2DHG, the charge accumulated on the metal must roughly equal the charge that was originally in the well (FIG. 7). The capacitance of the 2DHG, C_{2DHG}=−AdQ_{2D}/dV, is 13.0 pF, which compares well with the depletion capacitance 12.4 pF measured in extreme forward bias. Furthermore, from FIGS. 5A and 5B, the positive voltage region gives a 2DHG density of ˜3.8×10¹² cm⁻², which agrees well with the 2DHG concentration of ˜3.5×10¹² cm⁻² predicted [17].

In other experiments, thin 3C layers were grown on 4H semi-insulating substrates. The charge balance in such a situation is difficult to model realistically owing to the deep traps present in the substrate [18], which may play a significant role in the formation of the quantum well between the polytypes. The low frequency CV characteristic clearly shows the presence of a 2DHG. This 2DHG is not observable at much higher frequencies, which is believed to be due to the low hole mobility in SiC [19]. The total hole charge is 6.2×10¹² cm⁻², which agrees well with the extracted polarization in 4H SiC.

Further work in this system would involve the formation of ohmic contacts to the hole gas and eventual realization of a p-type high mobility transistor (PHMT). More realistic modeling of the 3C layer on semi-insulating substrates is needed.

3. Realization of SiC HEMTs

The lattice matched SiC heteropolytype system shows great promise for high electron mobility transistors (HEMTs). HEMT's produce high currents for fast switching microwave transistors by providing both high carrier concentrations together with high carrier mobility. Without a quantum well, high carrier concentration can only be achieved through doping, which severely degrades carrier mobility in concentrations much above 10¹⁷ cm⁻³. In order for HEMTs to be realized, the conduction in the (0001) plane must be understood. This is dependent on material quality and unintentional impurity concentration, as discussed previously. Because the 3C must be grown on on-axis SiC substrates, it is susceptible to being heavily twinned. The effect of twin boundaries, termed double positioning boundaries, (DPB's) on lateral conduction is unclear. It also suggests that these DPB's may affect the leakage of a gate Schottky metal. A systematic study of the effect of DPB's on conduction is needed in order to optimize the performance of SiC heteropolytype HEMTs. In addition, the usual issues of ohmic contact formation and optimization of gate metallization must be addressed.

FIG. 8 discloses a HEMT 10 made in accordance with the concepts of the present invention. The HEMT 10 includes a base 12 formed from either hex or rhomboid SiC, on top of which is a 3C SiC layer 14 that forms a heterojunction in the interface 15 between the two layers. Source, gate and drain contacts 16, 18 and 20 are formed in or on the 3C SiC layer. As illustrated the interface 15 results in formation of 2DEG on the C-face and 2DHG on Si-face that provide the charge transport mechanism for the HEMT.

4. Realization of Exotic Diodes:

The lattice matched SiC heteropolytype system also shows promise for Schottky diodes with low-turn on-voltage. The leakage in reverse bias can be engineered to reflect the wide bandgap side, while the forward voltage loss can be engineered to reflect the narrow bandgap side for high-voltage, low loss switching applications.

Another exotic diode application involves a structure such as FIGS. 4A and 4B. The presence of the polarization charge at the interface leads to a huge field in the narrow gap 3C region. Furthermore, the large conduction band offset (−1 eV) can be used to launch hot electrons into the high field 3C region, which may induce hot-electron effects such as negative differential resistance (NDR), which has been documented in SiC. Such hot-electron diodes find applications in realms such as high frequency oscillators for microwave and terahertz applications.

In summary, the polarization doped SiC channels appear to be suitable for high current devices. The C-face DEG displays significant current capability, while the Si-face 2DHG offers an alternative to p-channel MOSFETs in SiC, for high hole mobility devices. Both faces offer the possibility of exotic high performance diodes and other 2 or 3 terminal devices. The physical richness and technological promise of this heteropolytypic system offer commercialization opportunities in the field of high performance electron devices.

Although the invention has been disclosed in terms of preferred embodiment and variations thereon, it will be understood that numerous additional variations and modifications could be made thereto without departing from the scope of the invention as defined in the claims appended hereto.

### REFERENCES

[1] U. Starke, J. Schardt, J. Bernhardt, M. Franke, and K. Heinz, Phys. Rev. Lett., 82, 2107 (1999)
[2] C. Cheng, R. J. Needs and V Heine, J. Phys. C: Solid State Phys., 21, 1049 (1988)
[3] A. Qteish, Volker Heine, and R. J. Needs, Phys. Rev. B, 45, 6534 (1992)
[4] J. A. Powell, Herbert A. Will, J. Appl. Phys., 43, 1400 (1972)
[5] A. Fissel, J. Crystal Growth, 212, 438 (2000)
[6] S. Bai, R. P. Devaty, W. J. Choyke, U. Kaiser, M. F. MacMillan, Appl. Phys. Lett, 83, 3171 (2003)
[7] A. Fissel, Physics Reports, 379, 149 (2003)
[8] Hiroyuki Matsunami, Tsunenobu Kimoto, Mat. Sci. Eng. R20, 125 (1997)
[9] Glass, R. C.; Henshall, D.; Tsvetkov, V. F.; Carter, C. H., Jr., Phys. Stat. Sol (B), Appl. Res., 202, 149 (1997)
[10] Philip G. Neudeck, J. Anthony Powell, and Andrew J. Trunek, Xianrong R. Huang, and Michael Dudley, Mat. Sci. For. 389-293, 311 (2002)
[11] A. A. Lebedev, G. N. Mosina, I. P. Nikitina, N. S. Savkina, L. M. Sorokin and A. S. Tregubova, Tech. Phys. Lett., 27, 1052 (2006)
[12] H. S. Kong, J. T. Glass, R. F. Davis, Appl. Phys. Lett., 49, 1074 (1986)
[13] Tsunenobu Kimoto and Hiroyuki Matsunami, J. Appl. Phys., 78, 3132 (1995)
[14] David J. Larkin, Philip G. Neudeck, J. Anthony Powell, and Lawrence G. Matus, Appl. Phys. Lett., 65, 1659 (1994)
[15] V. M. Polyakov and F. Schwierz, J. Appl. Phys., 98, 023709 (2005)
[16] H. Kroemer, Wu-Yi Chien, J. S. Harris, Jr. and D. D. Edwall, Appl. Phys. Lett., 36, 295 (1980)
[17] M V S Chandrashekhar, C. I. Thomas, J. Lu, M. G. Spencer, submitted to Appl. Phys. Lett.
[18] Sghaier, N. Bluet, J.-M. Souifi, A. Guillot, G. Morvan, E. Brylinski, C., IEEE Trans. Elec. Dev., 50, 297 (2003).
[19] Hideharu Matsuura, Masahiko Komeda, Sou Kagamihara, Hirofumi Iwata, Ryohei Ishihara, Tetsuo Hatakeyama, Takatoshi Watanabe, Kazutoshi Kojima, Takashi Shinohe, Kazuo Arai, J. Appl. Phys., 96, 2708 (2004).

1. A heterojunction for use in 2 and 3 terminal high performance semiconductor devices, said heterojunction being formed from an interface between first and second lattice matched SiC polytypes, said heterojunction having an abrupt change in polarization which leads to 2 dimensional electron or hole gases at the interface, depending on the direction of polarization, thereby eliminating the need for conventional p type or n type doping.

2. The heterojunction of claim 1, wherein said first SiC polytype is 3SiC and said second SiC polytype is selected from the group comprising 4H—SiC and 6H—SiC.
